(19) United States
(12) Patent Application Publication
(10) Pub. No.: US 2023/0178695 A1
(43) Pub. Date: Jun. 8, 2023

(54) RADIATION-EMITTING SEMICONDUCTOR COMPONENT AND METHOD FOR PRODUCING A RADIATION-EMITTING SEMICONDUCTOR COMPONENT

(71) Applicant: ams-OSRAM International GmbH, Regensburg (DE)

(72) Inventors: Peter STAUSS, Regensburg (DE); Hubert HALBRITTER, Dietfurt-Toeging (DE)

(73) Assignee: ams-OSRAM International GmbH, Regensburg (DE)

(21) Appl. No.: 17/923,772

(22) PCT Filed: May 5, 2021
(86) PCT No.: PCT/EP2021/061835

§ 371 Date: Nov. 7, 2022

(30) Foreign Application Priority Data
May 7, 2020 (DE) 10 2020 112 414.7

(51) Int. Cl. H01L 33/58; H01L 33/42

(52) U.S. Cl. CPC H01L 33/58; H01L 33/42; H01L 2933/0016; H01L 2933/0058

(57) ABSTRACT

The invention relates to a radiation-emitting semiconductor component comprising a semiconductor body which has an active zone for generating radiation and a radiation exit surface, a contact element which is arranged on the radiation exit surface at a first lateral distance from a first edge piece of the radiation exit surface and at a second lateral distance from a second edge piece of the radiation exit surface, and a decoupling structure for improving the decoupling of the radiation generated by the active zone, which decoupling structure is arranged on the radiation exit surface and has structural elements, wherein the structural elements vary in such a way that the radiation decoupling increases from the contact element to the first and/or second edge piece. Furthermore, a method is specified for producing a such a radiation-emitting semiconductor element.

### CROSS-REFERENCE TO RELATED APPLICATIONS

The present application is a national stage entry from International Application No. PCT/EP2021/061835, filed on May 5, 2021, published as International Publication No. WO 2021/224324 A1 on Nov. 11, 2021, and claims priority to German Patent Application 10 2020 112 414.7 filed May 7, 2020, the disclosures of all of which are hereby incorporated by reference herein in their entireties.

### FIELD OF THE INVENTION

A radiation-emitting semiconductor component is specified which is suitable in particular for the emission of radiation at the longwave edge of the visible spectrum, preferably in the red to infrared range. Additionally specified is a method for producing such a radiation-emitting semiconductor component.

### BACKGROUND OF THE INVENTION

Radiation-emitting semiconductor components such as light-emitting diodes, for instance, generate electromagnetic radiation when an appropriate electrical current runs through them. For supplying with electrical current, the light-emitting diodes have electrical connection regions which are disposed, for example, centrally on surfaces of the light-emitting diodes. Particularly if distances from the center to the edge of the light-emitting diode are situated in the range of the diffusion length of the charge carriers, a high nonradiative recombination may occur at the edge. And the radiative recombination may have a gradient over the width of the light-emitting diode from its center to the edge, so that the radiation emitted from the light-emitting diode has an unequal distribution of radiation density.

One object to be achieved is presently that of specifying a radiation-emitting semiconductor component suitable for emitting radiation having a predominantly uniform radiation density profile. This object is achieved inter alia by a radiation-emitting semiconductor component having the features of the independent article claim.

A further object to be achieved is presently that of specifying a method for producing such a radiation-emitting semiconductor component. This object is achieved inter alia by a method having the features of the independent method claim.

### SUMMARY OF THE INVENTION

Advantageous developments of the radiation-emitting semiconductor component and of the method are subjects of the dependent claims.

According to at least one embodiment, the radiation-emitting semiconductor component comprises a semiconductor body which has a first semiconductor region of a first conductivity type, a second semiconductor region of a second conductivity type, and an active zone which is intended for emission of radiation and is disposed between the first and second semiconductor regions. Additionally the semiconductor body has a radiation exit face. Preferably a large part of the emitted radiation departs the semiconductor body, in operation, via the radiation exit face.

The radiation-emitting semiconductor component additionally comprises a contact element which is disposed at a first lateral distance from a first edge piece of the radiation exit face and at a second lateral distance from a second edge piece of the radiation exit face, on said face. The contact element is intended more particularly for the electrical contacting of the first semiconductor region.

The radiation-emitting semiconductor component additionally comprises a decoupling structure for improving the decoupling of the radiation emitted from the active zone, said structure being disposed at the radiation exit face and having structural elements, where the structural elements vary in such a way that the radiative decoupling increases starting from the contact element up to the first and/or second edge piece.

The structural elements preferably vary in their size and/or shape and/or their reciprocal distance. More preferably the size and/or the reciprocal distance of the structural elements increase starting from the contact element up to the first and/or second edge piece.

By means of the decoupling structure, which produces an increase in the radiative decoupling starting from the contact element up to the first and/or second edge piece, the radiative recombination and/or charge carrier density decreasing toward the first and/or second edge piece can be at least partly compensated.

The radiation-emitting semiconductor component or the semiconductor body preferably has a principal plane of extent which is spanned by a first lateral direction and a second lateral direction, the first and second lateral distances being determined in particular along the same lateral direction, preferably along the first lateral direction.

According to at least one embodiment, the first and second lateral distances are of equal magnitude. In particular the contact element is disposed in central position on the radiation exit face. The design of the contact element may be, for example, rectangular, in strip form or square, for instance, or circular. The shape of the contact element is preferably guided by the geometry of the semiconductor component or semiconductor body, which is described in more detail later on below.

The “size” of the structural elements presently refers in particular, respectively, to the extent in the first and second lateral directions and also in a vertical direction disposed perpendicular to said directions.

The “reciprocal distance” presently refers in particular to the distance between the barycenters of two directly adjacent structural elements. The reciprocal distance may, at close to the edge, correspond approximately to the wavelength of the radiation generated in the active zone.

It is possible for the decoupling structure to be part of the semiconductor body. In that case the semiconductor body may be structured at the radiation exit face in such a way that it has structural elements whose size and/or shape and/or reciprocal distance increase from inside to outside.

Furthermore, the decoupling structure may be a structured layer disposed at or on the radiation exit face. The structured layer may comprise, for example, a radiation-transmissive material. More particularly the radiation-transmissive material is transmissive for the radiation generated or emitted from the active zone. Suitable materials for the structured layer include, for example, a TCO, a dielectric material, such as SiO or SiN, or a glass, which may for example be low-melting. The structured layer may be structured in such a way that it has structural elements whose size and/or shape and/or reciprocal distance increase from inside to outside.

The structural elements are preferably projecting regions separated from one another for example by a coherent interspace. These structural elements may have a convex shape, for instance an at least approximately hemispherical architecture, a pyramidal, conical or cuboidal architecture.

In the case of one advantageous configuration of the radiation-emitting semiconductor component, the first semiconductor region is an n-conducting semiconductor region. Additionally, the second semiconductor region is more particularly a p-conducting semiconductor region. The first and second semiconductor regions and also the active zone may each have a plurality of consecutive semiconductor layers. The converse arrangement is also possible, however, with the first semiconductor region being a p-conducting or p-doped semiconductor region and the second semiconductor region being an n-conducting or n-doped semiconductor region. This is the case, for example, if the semiconductor body is flipped twice in the course of production.

The first and second semiconductor regions and also the active zone, or the layers they each contain, can be grown layer by layer, successively, on a growth substrate by means of an epitaxy process. Examples of suitable materials for the growth substrate include GaAs, InP, and germanium.

The growth substrate may remain in the semiconductor component or be at least partly removed. In the latter case the semiconductor regions may be disposed on a substitute carrier.

For the semiconductor body or layers of the semiconductor body, materials contemplated are preferably materials based on phosphide and/or arsenide compound semiconductors. “Based on phosphide and/or arsenide compound semiconductors” in this context means that a thus-designated semiconductor body or part of the semiconductor body comprises AlₙGaₘIn₁₋ₙ₋ₘAs_{y}P_{1-y}, where 0≤n 1, 0≤m≤1, n+m≤1 and 0≤y≤1. This material need not necessarily have a mathematically exact composition according to the formula above. It may instead comprise one or more dopants and also additional constituents which do not substantially change the physical properties of the material. For the sake of simplicity, however, the formula above contains only the essential constituents of the crystal lattice (Al, Ga, In, P, As), although it is possible for these constituents to have been replaced in part by small amounts of further substances.

In the case of one advantageous configuration of the radiation-emitting semiconductor component, the contact element comprises or consists of a transparent conductive oxide. Transparent conductive oxides (TCOs for short) are transparent, conducting materials, generally metal oxides, such as zinc oxide, tin oxide, cadmium oxide, titanium oxide, indium oxide or indium tin oxide (ITO), for example. As well as binary metal-oxygen compounds, such as ZnO, SnO₂ or In₂O₃, for example, the group of the TCOs also includes ternary metal-oxygen compounds, such as Zn₂SnO₄, CdSnO₃, ZnSnO₃, MgIn₂O₄, GaInO₃, Zn₂In₂O₅ or In₄Sn₃O₁₂, for example, or mixtures of different transparent conductive oxides. Moreover, the TCOs do not necessarily correspond to a stoichiometric composition and may also have p- or n-doping. The transparent embodiment of the contact element has the advantage that radiation generated beneath the contact element is also able to decouple from the semiconductor component.

The radiation-emitting semiconductor component may have a further contact element, which is disposed at a first lateral distance from a first edge piece of a semiconductor body bottom face lying opposite the radiation exit face, and at a second lateral distance from a second edge piece of the bottom face, on said face. The further contact element is preferably disposed in central position on the bottom face. The further contact element is intended more particularly for the electrical contacting of the second semiconductor region.

The radiation exit face is preferably a surface of the first semiconductor region that is facing away from the active zone, whereas the bottom face may be a surface of the second semiconductor region that is facing away from the active zone.

According to at least one embodiment, the radiation-emitting semiconductor component is a micro-LED having at least one lateral extent in the micrometer range. The radiation-emitting semiconductor component preferably has a first lateral extent which is at least 10 μm and at most 50 μm, more particularly 25 μm. The first lateral extent is determined, in particular, parallel to the first lateral direction.

In the case of one advantageous configuration, the radiation-emitting semiconductor component has a rectangular or strip-shaped design in plan view onto the radiation exit face, and has a second lateral extent which is greater than the first lateral extent and is, for example, at least 1 mm and at most 5 mm. The second lateral extent is determined, in particular, parallel to the second lateral direction.

In the case of another embodiment, the radiation-emitting semiconductor component is of circular or square design in plan view onto the radiation exit face and has a second lateral extent which is at least 10 μm and at most 50 μm. The first and second lateral extents are in this case preferably of equal magnitude.

According to at least one embodiment, the decoupling structure is of symmetrical design in respect of the contact element. For example, the contact element may be of rectangular or strip-shaped design, and the decoupling structure has an at least largely axisymmetrical design in respect of the contact element. Moreover, the contact element may be circular or square in design, and the decoupling structure has an at least largely rotationally symmetrical design in respect of the contact element.

According to at least one embodiment, the radiation-emitting semiconductor component has a cover element which is disposed on the edge side of the radiation exit face. The cover element is intended to clearly delimit the emission profile of the semiconductor component at the edge. Suitable materials include reflective materials such as Ag, for instance. Absorbing materials as well, especially blackening materials, are suitable for the cover element.

In the case of one advantageous configuration, the cover element is of frame-like design. In particular the radiation exit face is covered at the edge on all sides by the cover element.

According to at least one embodiment, the semiconductor body has a passivation formed on the edge side. The passivation advantageously produces a reduction in the nonradiative recombination at the edge.

Described below is a method which is suitable for producing a radiation-emitting semiconductor component described above. Features described in connection with the semiconductor component may therefore also be employed for the method, and vice versa.

According to at least one embodiment of a method for producing a radiation-emitting semiconductor component, a semiconductor body is provided which comprises a first semiconductor region of a first conductivity type, a second semiconductor region of a second conductivity type, and an active zone which is intended for emission of radiation and is disposed between the first and second semiconductor regions. Furthermore, the semiconductor body which is provided has a radiation exit face. There is additionally a contact element formed which is disposed at a first lateral distance from a first edge piece of the radiation exit face and at a second lateral distance from a second edge piece of the radiation exit face, on said face. Moreover, a decoupling structure is formed on the radiation exit face for improving the decoupling of the radiation emitted from the active zone, comprising structural elements, where the structural elements are varied in such a way that the radiative decoupling increases starting from the contact element up to the first and/or second edge piece.

The structural elements are preferably varied in their size and/or shape and/or their reciprocal distance.

For example, the decoupling structure may be a structured layer formed at or on the radiation exit face. The structured layer comprises, for example, a radiation-transmissive material. This radiation-transmissive material is transmissive more particularly for the radiation generated or emitted from the active zone.

The decoupling structure may be produced by means of a structuring process such as photolithography or nanoimprinting, for instance.

In the case of photolithography, a mask is preferably used whose radiation transmissiveness varies in the pattern of the decoupling structure to be generated. A photosensitive layer disposed on the semiconductor body can be exposed through the mask. In the course of the exposure, a mask structure, resulting from regions of higher and lower radiation transmissiveness, is transferred into the photosensitive layer. By means of the photosensitive layer, the mask structure can be transferred further into underlying layers of the semiconductor component—for example, into an insulating layer, which contains SiO or SiN, for instance, or into a contact layer, which contains TCO in particular, or into the semiconductor body.

According to at least one embodiment, the decoupling structure is formed by the application to the radiation exit face of a contact layer which comprises TCO and is structured in such a way that it has structural elements whose size and/or reciprocal distance increase from inside to outside.

The decoupling structure may also be formed by the application to the radiation exit face of an insulating layer which comprises a dielectric material and is structured in such a way that it has structural elements whose size and/or reciprocal distance increase from inside to outside.

According to a further embodiment, the decoupling structure is formed by the structuring of the semiconductor body, on the radiation exit face, in such a way that said body has structural elements whose size and/or reciprocal distance increase from inside to outside.

A multiplicity of radiation-emitting semiconductor components are produced preferably in wafer assemblage, with the wafer assemblage being singulated with particular preference after the production of the decoupling structures.

Radiation-emitting semiconductor components of the kind described here, which may take the form of striplike micro-LEDs, are suitable—on the basis of the elongated shape which already covers one dimension—as light sources in scanning devices, as for example in 1D MEMS scanners for the scanning of an eye position or pupil or in barcode readers for the scanning of a product barcode.

### BRIEF DESCRIPTION OF THE DRAWINGS

Further advantages, preferred embodiments and developments of the semiconductor component and also of the method are apparent from the exemplary embodiments elucidated below in connection with FIGS. 1 to 5.

In the figures:

FIG. 1 shows a schematic cross-sectional view of a radiation-emitting semiconductor component according to a first exemplary embodiment,

FIG. 2D shows a schematic cross-sectional view of a radiation-emitting semiconductor component according to a comparative example, FIG. 2A shows a diagram representing a radiation density profile to be achieved over a width of the radiation-emitting semiconductor component, FIG. 2B shows a diagram representing a profile of radiative recombination over the width of the radiation-emitting semiconductor component, FIG. 2C shows a diagram representing different variants of a decoupling efficiency to be achieved over the width of the radiation-emitting semiconductor component, and FIG. 2E shows a schematic plan view of the radiation-emitting semiconductor component represented in FIG. 2D, according to the comparative example,

FIG. 3 shows a diagram representing profiles of radiative recombination of different variants of radiation-emitting semiconductor components according to the comparative example,

FIGS. 4A and 4B show various steps of a method for producing—and FIG. 4B a schematic cross-sectional view of—a radiation-emitting semiconductor component according to a second exemplary embodiment,

FIGS. 5A and 5B show various steps of a method for producing—and FIG. 5B a schematic cross-sectional view of—a radiation-emitting semiconductor component according to a third exemplary embodiment.

### DETAILED DESCRIPTION

In the exemplary embodiments and figures, elements which are the same, of the same kind or have the same effect may each be given the same reference symbols. The elements represented and their proportions among one another should not necessarily be regarded as being true to scale; instead, individual elements may be represented with exaggerated magnitude for the purpose of greater ease of representation and/or of better comprehension.

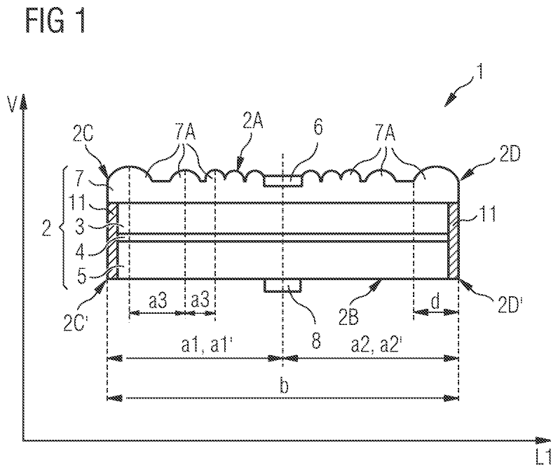

FIG. 1 represents a first exemplary embodiment of a radiation-emitting semiconductor component 1. The radiation-emitting semiconductor component 1 has a semiconductor body 2, which comprises a first semiconductor region 3 of a first conductivity type, a second semiconductor region 5 of a second conductivity type, and an active zone 4 for the emission of radiation, disposed between the first and second semiconductor regions 3, 5. The semiconductor component 1 is intended preferably for emission of radiation at the longwave edge of the visible spectrum, more preferably in the red to infrared spectral range. The wavelength here may be between 600 nm inclusive and 1500 nm inclusive.

In particular, the first semiconductor region 3 is an n-conducting or n-doped semiconductor region and the second semiconductor region 5 is a p-conducting or p-doped semiconductor region. It is, however, also possible for the reverse situation to apply, and for the first semiconductor region 3 to be a p-conducting or p-doped semiconductor region and the second semiconductor region 5 to be an n-conducting or n-doped semiconductor region. This is the case, for example, if the semiconductor body 2 is flipped twice in the course of production.

For the regions 3, 4, 5 of the semiconductor body 2, or for layers contained in the semiconductor body 2 or the regions 3, 4, 5, suitable materials are preferably III/V semiconductor materials, more preferably materials from the material system AlₙGaₘIn₁₋ₙ₋ₘAs_{y}P_{1-y}, where 0≤n≤1, 0≤m≤1, n+m≤1, and 0≤y≤1.

Furthermore, the semiconductor body 2 has a radiation exit face 2A which is disposed on a side of the first semiconductor region 3 that is facing away from the active zone 4. Preferably a large part of the radiation generated in operation departs the semiconductor body 2 via the radiation exit face 2A. More particularly the radiation-emitting semiconductor component 1 may be a surface emitter. The emission characteristics of a surface emitter, in the case of the semiconductor component 1 represented in FIG. 1, may be achieved inter alia by at least partial removal of a growth substrate used for producing the regions 3, 4, 5.

The radiation-emitting semiconductor component 1 further comprises a decoupling structure 7, which is disposed on the radiation exit face 2A and is part of the semiconductor body 2. In the case of the first exemplary embodiment, therefore, the decoupling structure 7 is formed of a semiconductor material.

The decoupling structure 7 has structural elements 7A which vary in such a way that the radiative decoupling increases starting from a contact element 6 up to a first and/or second edge piece 2C, 2D.

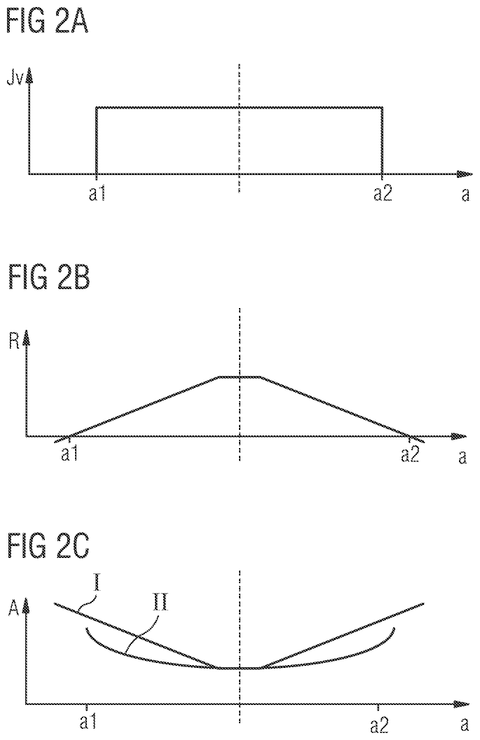

In particular, a first lateral extent d of the structural elements 7A, which is determined parallel to a first lateral direction L1, and hence also the magnitude thereof, increases from inside to outside. Furthermore, a reciprocal distance a3 of the structural elements 7A, which is determined parallel to a principal plane of extent, spanned by the first lateral direction L1 and by a second lateral direction L2 disposed perpendicular to it (cf. FIG. 2E), may also increase from inside to outside.

The structural elements 7A have a convex, at least approximately hemispherical architecture. The reciprocal distance a3 between the structural elements 7A preferably corresponds, close to the edge 2C, 2D, approximately to the wavelength of the radiation generated in the active zone 4.

The contact element 6 is disposed at a first lateral distance a1 from the first edge piece 2C of the radiation exit face 2A and at a second lateral distance a2 from the second edge piece 2D of the radiation exit face 2A, on said face, with the first and second distances a1, a2 being determined parallel to the first lateral direction L1. Advantageously the size and reciprocal distance a3 between the structural elements 7A increase starting from the contact element 6 up to the first and second edge pieces 2C, 2D. In other words, the structural elements 7A disposed in the vicinity of the contact element 6 are smaller than the structural elements 7A disposed on the edge pieces 2C, 2D. As a result it is possible to achieve an increase in the radiative decoupling starting from the contact element 6 up to the first and second edge pieces 2C, 2D. The radiative recombination decreasing toward the first and second edge pieces 2C, 2D may therefore be at least partly compensated by the decoupling structure 7.

The first and second lateral distances a1, a2 are preferably of equal magnitude. In particular the contact element 6 is disposed in central position on the radiation exit face 2A. For example, the radiation-emitting semiconductor component 1 may have a first lateral extent b which is at least 10 μm and at most 50 μm, so that the first and second lateral distances a1, a2 are each between at least 5 μm and at most 25 μm.

The first semiconductor region 3 can be contacted electrically by means of the contact element 6. The contact element 6 advantageously comprises or consists of a transparent conductive oxide. The transparent design of the contact element 6 has the advantage that radiation generated beneath the contact element 6 can also be decoupled from the semiconductor component 1.

The contact element 6 may be rectangular, for instance strip-shaped or square, or circular in design, with the geometry of the contact element 6 preferably corresponding to the geometry of the semiconductor component 1 or semiconductor body 2.

The decoupling structure 7 is of symmetrical design in respect of the contact element 6. For example, the contact element may be of strip-shaped design (cf. FIG. 2E), with the decoupling structure 7 being of at least largely axisymmetrical design in respect of the contact element 6. Moreover, the contact element 6 may be of circular or square design, with the decoupling structure 7 being of at least largely rotationally symmetrical design in respect of the contact element 6.

The semiconductor body 2 has a passivation 11 formed on the edge side. The passivation 11 advantageously produces a reduction in the nonradiative recombination at the edge.

The radiation-emitting semiconductor component 1 has a further contact element 8, which is disposed at a first lateral distance a1′ from a first edge piece 2C′ of a bottom face 2B of the semiconductor body 2, lying opposite the radiation exit face 2A, and at a second lateral distance a2′ from a second edge piece 2D′ of the bottom face 2B, on said face. In particular the further contact element 8 is disposed in central position on the bottom face 2B and is intended for the electrical contacting of the second semiconductor region 5.

The radiation-emitting semiconductor component 1 advantageously has emission behavior of “Top-Head” kind, meaning in particular that the decoupled radiation has a flat beam profile, with the intensity of the radiation remaining substantially the same over the radiation exit face 2A. A beam profile of this kind is represented for example in FIG. 2A.

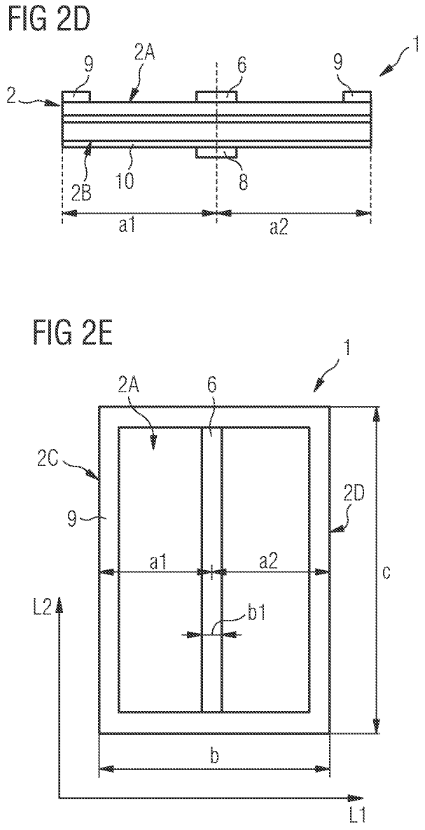

The problem on which the invention is based, and the solution to the problem, are elucidated in more detail in connection with FIGS. 2A to 2E and FIG. 3.

FIG. 2D shows a comparative example of a radiation-emitting semiconductor component 1, which has a semiconductor body 2 having a radiation exit face 2A and a bottom face 2B, a contact element 6 disposed on the radiation exit face 2A, and a cover element 9 disposed on the radiation exit face 2A, for obtaining a clearly delimited luminous area, and a further contact element 8 disposed on the bottom face 2B. Additionally the radiation-emitting semiconductor component 1 has a reflection layer 10 disposed on the bottom face 2B. In contradistinction to the radiation-emitting semiconductor component 1 according to the first exemplary embodiment, the radiation-emitting semiconductor component 1 according to the comparative example does not have a decoupling structure.

As is apparent from FIG. 2E, the radiation-emitting semiconductor component 1 is of rectangular, more particularly strip-shaped, design in plan view onto the radiation exit face 2A, and has a second lateral extent c which is at least 1 mm and at most 5 mm. This second lateral extent c is determined parallel to the second lateral direction L2.

The cover element 9 is of frame-like design, with the radiation exit face 2A being covered by the cover element 9 all round at the edge. Suitable materials include reflective materials such as Ag, for instance. Absorbing materials, more particularly blackening materials, are also suitable for the cover element 9.

The contact element 6 has a geometry which is adapted to the geometry of the semiconductor component 1, likewise in strip form. The first lateral extent b1 of the contact element 6 is preferably between 1 μm and 8 μm, preferably between 1 μm and 2 μm.

As is apparent from the diagram of FIG. 2B, the radiative recombination R decreases continuously, more particularly linearly, with the distance a from the center of the semiconductor component 1. One reason for this is that the distances a1, a2 are each situated in the range of the diffusion lengths of the charge carriers. The nonradiative recombination also increases owing to surface defects at the edge 2C, 2D of the semiconductor body 2.

FIG. 2C represents different profiles I, II of advantageous decoupling efficiencies A, which enable compensation of the decreasing radiative recombination R, so that a “Top-Head”-kind distribution of the luminance Jv as represented in FIG. 2A can be achieved. In the ideal case the decoupling efficiency A represents an inverse function (curve I) of the radiative recombination R. Also sufficient in fact, however, is a function approximated to the ideal curve I, and equating to a parabola like the curve II, for example.

FIG. 3 illustrates the results of various simulations for investigating the radiative recombination R. Parameters changed here were firstly the first lateral extent b1 of the contact element 6 (KI, KIII: b1=2 μm; KII, KIV: b1=8 μm) and secondly the edge passivation (KI, KII: without passivation; KIII, KIV: with passivation).

In the diagram of FIG. 3, the radiative recombination R [E28 cm-3/s] is plotted against the first lateral distance a [μm] from the center of the semiconductor component 1. The semiconductor component 1 has a first lateral extent b of 10 μm. The x-axis section “0” corresponds to the center of the semiconductor component 1. The x-axis section “5 μm” corresponds to the second edge piece 2D of the semiconductor component 1.

The curve III with maximum radiative recombination R shows a sharp gradient at the edge. As a result of the edge passivation, however, it is already possible to reduce the nonradiative recombination, as is clear from the comparison with curves I, II. The decrease at the edge can be at least partly compensated by the decoupling structure 7 (cf. FIGS. 1, 4B, 5B).

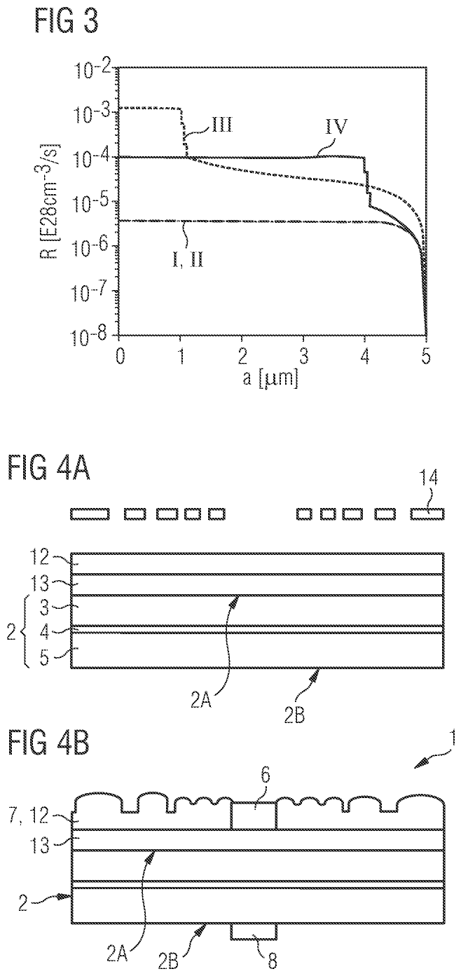

FIGS. 4A and 4B represent various steps in a method for producing a radiation-emitting semiconductor component 1 according to a second exemplary embodiment. FIG. 4B shows a radiation-emitting semiconductor component 1 according to the second exemplary embodiment.

Provided first of all is a semiconductor body 2, which comprises a first semiconductor region 3 of a first conductivity type, a second semiconductor region 5 of a second conductivity type, and an active zone 4 which is intended for emission of radiation and is disposed between the first and second semiconductor regions 3, 5. The semiconductor body 2 further comprises a radiation exit face 2A.

Applied successively to the radiation exit face 2A are a contact layer 13 and an insulating layer 12. The contact layer 13 preferably comprises or consists of TCO. The insulating layer 12 comprises or consists of a dielectric material, such as SiO or SiN, for example. The materials of the contact and insulating layers 13, 12 are advantageously transmissive for the radiation generated in the active zone 4.

The insulating layer 12 is structured by means of photolithography to generate a decoupling structure 7 which is disposed at or on the radiation exit face 2A. During the photolithography, a mask 14 is used whose radiation transmissiveness varies in the pattern of the decoupling structure 7 that is to be generated.

It is possible first to expose, through the mask 14, a photosensitive layer which is disposed on the semiconductor body 2 (not represented). In the course of the exposure, a mask structure resulting from regions with higher and lower radiation transmissiveness is transferred into the photosensitive layer. By means of the photosensitive layer, the mask structure can be transferred further into the insulating layer 12.

In the case of the first exemplary embodiment represented in FIG. 1, the mask structure is transferred correspondingly into the semiconductor body 2.

After the structuring of the insulating layer 12, contact elements 6, 8 can be applied on the radiation exit face 2A and the opposite bottom face 2B. In particular the contact element 6 is applied directly to the contact layer 13 in an opening in the insulating layer 12.

The radiation-emitting semiconductor component 1 produced in this way has the advantages already stated above.

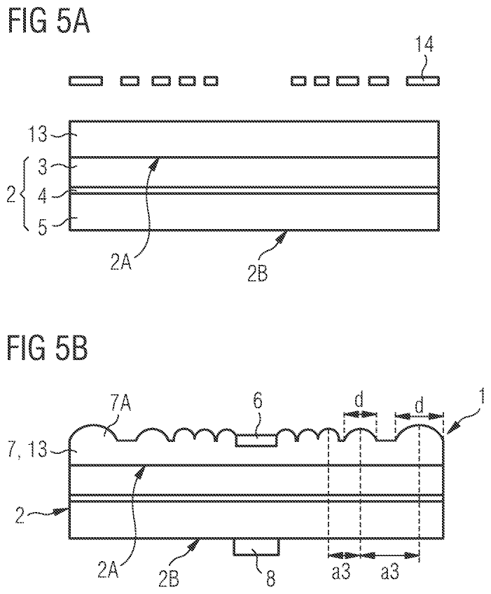

FIG. 5B shows a third exemplary embodiment of a radiation-emitting semiconductor component 1, and FIGS. 5A and 5B show various steps in a method for producing said component.

According to the third exemplary embodiment, an insulating layer is omitted, and the decoupling structure 7 is formed by the application to the radiation exit face 2A of a contact layer 13 which comprises TCO and is structured in such a way that it has structural elements 7A whose size or first lateral extent d and reciprocal distance a3 increase from inside to outside.

The radiation-emitting semiconductor component 1 produced in this way has the advantages already stated earlier on above.

According to advantageous configurations, the radiation-emitting semiconductor components 1 according to the first to third exemplary embodiments may have a reflection layer 10 disposed on the bottom face 2B corresponding to the comparative example represented in FIG. 2D. Additionally or alternatively, the radiation-emitting semiconductor components 1 according to the first to third exemplary embodiments may have a cover element 9 disposed on the radiation exit face 2A, corresponding to the comparative example represented in FIG. 2D. Furthermore, the radiation-emitting semiconductor components 1 according to the second and third exemplary embodiments may have an edge passivation 11 corresponding to the first exemplary embodiment represented in FIG. 1.

The invention is not restricted by the description in relation to the exemplary embodiments. The invention instead encompasses each new feature and also each combination of features, including in particular each combination of features in the claims, even if that feature or that combination is not itself explicitly specified in the claims or exemplary embodiments.

1. A radiation-emitting semiconductor component comprising
a semiconductor body comprising
a first semiconductor region of a first conductivity type,
a second semiconductor region of a second conductivity type, and
an active zone which is intended for emission of radiation and is disposed between the first and second semiconductor regions, and
a radiation exit face,
a contact element which is disposed at a first lateral distance from a first edge piece of the radiation exit face and at a second lateral distance from a second edge piece of the radiation exit face, on said face, and
a decoupling structure for improving the decoupling of the radiation emitted from the active zone, where the decoupling structure is a structured layer which is disposed at or on the radiation exit face and comprises a radiation-transmissive material, and has structural elements, wherein
the structural elements vary in such a way that the radiative decoupling increases starting from the contact element up to the first and/or second edge piece.

2. The radiation-emitting semiconductor component as claimed in claim 1, wherein the structural elements vary in their size and/or shape and/or their reciprocal distance.

3. The radiation-emitting semiconductor component as claimed in claim 1, wherein size and/or reciprocal distance of the structural elements increase starting from the contact element up to the first and/or second edge piece.

4. The radiation-emitting semiconductor component as claimed in claim 1, comprising a cover element, where the cover element is disposed on an edge side of the radiation exit face.

5. The radiation-emitting semiconductor component as claimed in claim 4, wherein the cover element is of frame-like design.

6. The radiation-emitting semiconductor component as claimed in claim 1, wherein the contact element is disposed in central position on the radiation exit face.

7. The radiation-emitting semiconductor component as claimed in claim 1, wherein the decoupling structure is designed symmetrically in respect of the contact element.

8. The radiation-emitting semiconductor component as claimed in claim 1, having a first lateral extent which is at least 10 μm and at most 50 μm.

9. The radiation-emitting semiconductor component as claimed in claim 1, being of rectangular design in plan view onto the radiation exit face and having a second lateral extent which is at least 1 mm and at most 5 mm.

10. The radiation-emitting semiconductor component as claimed in claim 9, wherein the contact element is of rectangular design and the decoupling structure is of at least largely axisymmetrical design in respect of the contact element.

11. The radiation-emitting semiconductor component as claimed in claim 1, being of circular or square design in plan view onto the radiation exit face and having a second lateral extent which is at least 10 μm and at most 50 μm.

12. The radiation-emitting semiconductor component as claimed in claim 11, wherein the contact element is of circular or square design and the decoupling structure is of at least largely rotationally symmetrical design in respect of the contact element.

13. The radiation-emitting semiconductor component as claimed in claim 1, wherein the semiconductor body comprises AlₙGaₘIn₁₋ₙ₋ₘAs_{y}P_{1-y}, where 0≤n≤1, 0≤m≤1, n+m≤1 and 0≤y≤1.

14. The radiation-emitting semiconductor component as claimed in claim 1, wherein the semiconductor body has a passivation formed on an edge side.

15. A method for producing a radiation-emitting semiconductor component as claimed in claim 1, comprising:
providing a semiconductor body comprising
a first semiconductor region of a first conductivity type,
a second semiconductor region of a second conductivity type, and
an active zone which is intended for emission of radiation and is disposed between the first and second semiconductor regions, and
a radiation exit face,
forming a contact element which is disposed at a first lateral distance from a first edge piece of the radiation exit face and at a second lateral distance from a second edge piece of the radiation exit face, on said face, and
forming a decoupling structure at or on the radiation exit face for improving the decoupling of the radiation emitted from the active zone, where the decoupling structure is a structured layer which comprises a radiation-transmissive material, and comprises structural elements, where the structural elements are varied in such a way that the radiative decoupling increases starting from the contact element up to the first and/or second edge piece.

16. The method as claimed in claim 15, wherein the decoupling structure is formed by an application to the radiation exit face of a contact layer which comprises TCO and is structured in such a way that it has structural elements whose size and/or reciprocal distance increase from inside to outside.

17. The method as claimed in claim 15, wherein the decoupling structure is formed by an application to the radiation exit face of an insulating layer which comprises a dielectric material and is structured in such a way that it has structural elements whose size and/or reciprocal distance increase from inside to outside.
